(19) United States
(12) Patent Application Publication
(10) Pub. No.: US 2008/0048205 A1
(43) Pub. Date: Feb. 28, 2008

(54) Optical semiconductor device and method for making the same

(75) Inventor: Tadahiro Okazaki, Kyoto (JP)

Correspondence Address: HAMRE, SCHUMANN, MUELLER & LARSON, P.C., P.O. BOX 2902, MINNEAPOLIS, MN, 55402-0902, US

(73) Assignee: ROHM CO., LTD., Kyoto-shi (JP)

(21) Appl. No.: 11/894,315

(22) Filed: Aug. 21, 2007

(30) Foreign Application Priority Data
Aug. 22, 2006 (JP) 2006-225440

(51) Int. Cl. H01L 33/00

(52) U.S. Cl. 257/99; 438/26; 257/E33.059; 257/E33.062

(57) ABSTRACT

An optical semiconductor device includes an insulating substrate provided with a first electrode and a second electrode each extending from the obverse surface onto the reverse surface of the substrate. The first electrode includes a die-bonding pad extending on the obverse surface of the substrate and a first terminal extending on the reverse surface of the substrate. The second electrode includes a wire-bonding pad extending on the obverse surface of the substrate and a second terminal extending on the reverse surface of the substrate. An LED chip is bonded to the die-bonding pad of the first electrode. The LED chip is also connected to the wire-bonding pad of the second electrode by a wire. The wire and the LED chip are enclosed by a resin package. The wire-bonding pad has a thickness of 10 μm-30 μm, and the second terminal has a thickness of 5 μm-9 μm.

### BACKGROUND OF THE INVENTION

1. Field of the Invention

The present invention relates to an optical semiconductor device configured to be surface-mounted on e.g. a circuit board. The present invention also relates to a method of making such an optical semiconductor device.

2. Description of the Related Art

FIG. 13 illustrates an example of a conventional optical semiconductor device (see JP-A-2001-196641, for example). The illustrated optical semiconductor device X includes a substrate 91, a pair of electrodes 92A, 92B, and an LED chip 93. The LED chip 93 is mounted on the electrode 92A and is connected to the electrode 92B via a wire 94. The LED chip 93 and the wire 94 are covered by a resin package 95.

The electrode 92A includes a base layer 92Aa and two plating layers 92Ab, 92Ac. As shown in FIG. 13, the electrode 92A extends from the upper surface of the substrate 91, through a side surface of the substrate, onto the lower surface of the substrate. Similarly, the electrode 92B, including a base layer 92Ba and two plating layers 92Bb, 92Bc, extends from the upper surface of the substrate 91, through the other side surface of the substrate, and onto the lower surface of the substrate. The base layers 92Aa, 92Ba are made of Cu, for example. The plating layers 92Ab, 92Bb are made of Ni, for example, and the plating layers 92Ac, 92Bc are made of Au, for example. The plating layer 92Bc has a relatively large thickness (1-2 μm for example) for reliable bonding of the wire 94 to the electrode 92B.

In making the optical semiconductor device X, the plating layers 92Ab and 92Bb are simultaneously formed in the same process. Thus, the plating layer 92Ab also has a relatively large thickness as the plating layer 92Bb. However, when the thickness of the plating layers 92Ab, 92Bb is large, the whole thickness of these layers may have variations. Excessively large variations may cause a problem in manufacturing process of the optical semiconductor device X after forming the plating layers 92Ab, 92Bb. Further, the plating layers 92Ab, 92Bb with excessively large thickness may increase the cost of the optical semiconductor device X.

### SUMMARY OF THE INVENTION

The present invention has been proposed under the above-described circumstances. It is therefore an object of the present invention to provide an optical semiconductor device that is produceable with ease and at low cost. Another object of the present invention is to provide a method of making such an optical semiconductor device.

According to a first aspect of the present invention, there is provided an optical semiconductor device comprising: an insulating substrate including an obverse surface, a reverse surface, and first and second ends spaced from each other; a first electrode provided at the first end and extending from the obverse surface onto the reverse surface, where the first electrode includes a die-bonding pad and a first terminal, the die-bonding pad extending on the obverse surface, the first terminal extending on the reverse surface; a second electrode provided at the second end and extending from the obverse surface onto the reverse surface, where the second electrode includes a wire-bonding pad and a second terminal, the wire-bonding pad extending on the obverse surface, the second terminal extending on the reverse surface; an LED chip bonded to the die-bonding pad; a wire for connecting the LED chip and the wire-bonding pad to each other; and a resin package enclosing the LED chip and the wire. The wire-bonding pad has a thickness of 10 μm-30 μm, while the second terminal has a thickness of 5 μm-9 μm.

Preferably, each of the first and the second electrodes may comprise a base layer and a plating layer formed on the base layer.

Preferably, the die-bonding pad may have a thickness of 10 μm-30 μm, while the first terminal may have a thickness of 5 μm-9 μm.

According to a second aspect of the present invention, there is provided an optical semiconductor device comprising: an insulating substrate including an obverse surface, a reverse surface, and first and second ends spaced from each other; a first electrode provided at the first end and extending from the obverse surface onto the reverse surface, the first electrode including a die-bonding pad and a first terminal, the die-bonding pad extending on the obverse surface, the first terminal extending on the reverse surface; a second electrode provided at the second end and extending from the obverse surface onto the reverse surface, the second electrode including a wire-bonding pad and a second terminal, the wire-bonding pad extending on the obverse surface, the second terminal extending on the reverse surface; an LED chip bonded to the die-bonding pad; a wire for connecting the LED chip and the wire-bonding pad to each other; and a resin package enclosing the LED chip and the wire. The die-bonding pad has a thickness of 10 μm-30 μm, and the first terminal has a thickness of 5 μm-9 μm.

According to a third aspect of the present invention, there is provided a method of making an optical semiconductor device. The method comprises the steps of: forming first and second electrodes on an insulating substrate including an obverse surface and a reverse surface, where each of the electrodes extends from the obverse surface onto the reverse surface, and includes a base layer and a plating layer formed on the base layer; bonding an LED chip to a die-bonding pad of the first electrode, where the die-bonding pad extends on the obverse surface; and connecting the LED chip and a wire-bonding pad of the second electrode by a wire, where the wire-bonding pad extends on the obverse surface. The forming of the first and the second electrodes includes a first plating step and a second plating step. In the first plating step, a plating layer is formed on portions of the base layer other than a terminal portion extending on the reverse surface. In the second plating step, another plating layer is formed at least on the terminal portion of the base layer.

Other features and advantages of the present invention will become apparent from the detailed description given below with reference to the accompanying drawings.

### BRIEF DESCRIPTION OF THE DRAWINGS

FIG. 1 is a perspective view showing an optical semiconductor device according to a first embodiment of the present invention;

FIG. 2 is a sectional view taken along lines II-II in FIG. 1;

FIG. 3 is a perspective view showing a material substrate used for producing optical semiconductor devices of the first embodiment;

FIG. 4 is a perspective view showing a part of the material substrate;

FIG. 5 is a perspective view showing a resist film forming step in a process of making optical semiconductor devices of the first embodiment;

FIG. 6 is a perspective view showing a base layer pattering step in the process;

FIG. 7 is a sectional view showing a plating layer forming step in the process;

FIG. 8 is a sectional view showing a resist film forming step in the process;

FIG. 9 is a sectional view showing a base layer pattering step in the process;

FIG. 10 is a sectional view showing a plating layer forming step in the process;

FIG. 11 is a sectional view showing an optical semiconductor device according to a second embodiment of the present invention;

FIG. 12 is a sectional view showing a plating layer forming step in a process of making optical semiconductor devices of the second embodiment; and

FIG. 13 is a sectional view showing a conventional optical semiconductor device.

### DESCRIPTION OF THE PREFERRED EMBODIMENTS

Preferred embodiments of the present invention will be described below with reference to the drawings.

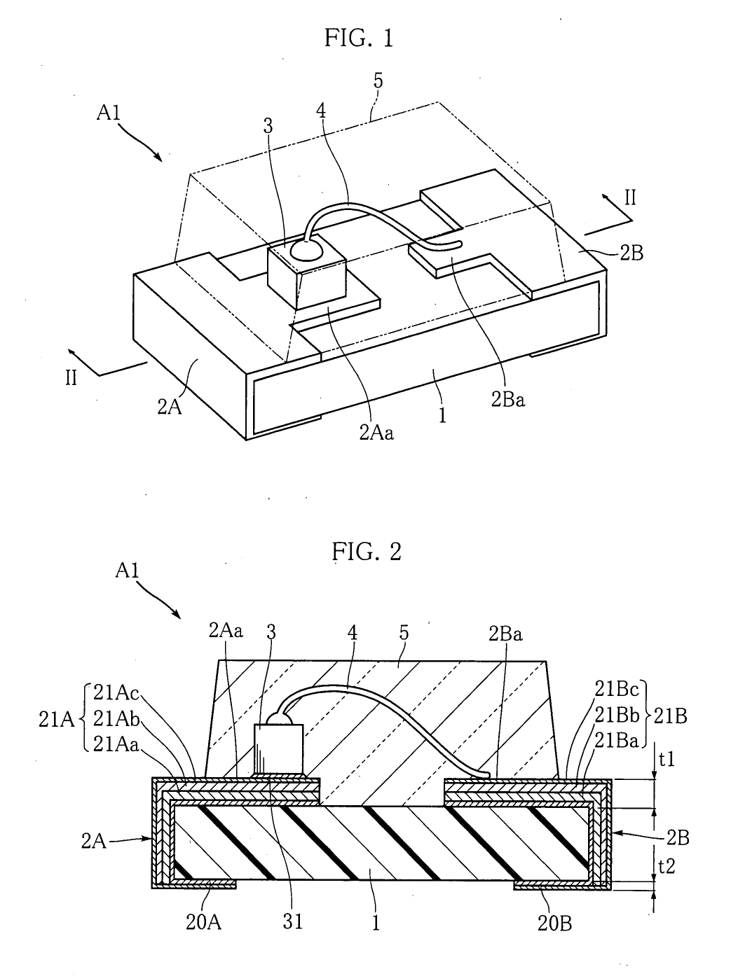

FIGS. 1 and 2 illustrate an optical semiconductor device according to a first embodiment of the present invention.

The illustrated optical semiconductor device A1 includes a substrate 1, a pair of electrodes 2A and 2B, an LED chip 3, a bonding wire 4, and a resin package 5. In FIG. 1, the resin package 5 is shown by imaginary lines.

The substrate 1 is a rectangular insulating substrate made of a glass epoxy resin, for example. The obverse surface of the substrate 1 supports the LED chip 3. In surface-mounting of the optical semiconductor device A1, the reverse surface of the substrate 1 is fixed to e.g. a circuit board.

The electrodes 2A, 2B are provided at two ends of the substrate 1 that are spaced from each other in the longitudinal direction of the substrate 1. Accordingly, the electrodes 2A, 2B are also spaced from each other in the longitudinal direction, thereby sandwiching the middle portion of the substrate 1. Each of the electrodes 2A, 2B covers an area extending from the obverse surface, through one of the side surfaces, and onto the reverse surface of the substrate 1. The electrode 2A (first electrode) includes a die-bonding pad 2Aa overlapping the obverse surface of the substrate 1. The electrode 2B (second electrode) includes a wire-bonding pad 2Ba overlapping the obverse surface of the substrate 1. The portions of the electrodes 2A, 2B overlapping the reverse surface of the substrate 1 are used as mounting terminals (first and second terminals) for surface-mounting of the optical semiconductor device A1.

As shown in FIG. 2, the first electrode 2A includes a base layer 20A and a plating layer 21A laminated thereon, and the second electrode 2B includes a base layer 20B and a plating layer 21B laminated thereon. The base layers 20A, 20B are formed of Cu by electroless plating, and have a thickness of about 5 μm-9 μm (that is, no smaller than 5 μm and no greater than 9 μm).

The plating layer 21A has a laminated structure of a first layer 21Aa, a second layer 21Ab and a third layer 21Ac. Likewise, the plating layer 21B has a laminated structure of a first layer 21Ba, a second layer 21Bb and a third layer 21Bc. The first layers 21Aa, 21Ba are formed of Ni, for example, and overlap the obverse surface and the side surfaces. The first layers 21Aa, 21Ba have a thickness of about 5 μm-20 μm. The second layers 21Ab, 21Bb are formed of Au by electrolytic plating, for example, and overlap the first layers 21Aa, 21Ba. The second layers 21Ab, 21Bb have a thickness of about 0.1 μm-0.2 μm. The third layers 21Ac, 21Bc are formed of Au by flash plating, for example, and overlap an area extending from the obverse surface, through one of the side surfaces, and onto the reverse surface of the substrate 1. The third layers 21Ac, 21Bc have a thickness of about 0.05 μm-0.3 μm. With the above layers, the electrodes 2A, 2B have a thickness t1 of 10 μm-30 μm at the portion covering the obverse surface and the side surfaces of the substrate 1, and a thickness t2 of 5 μm-9 μm at the portion covering the reverse surface of the substrate 1.

The LED chip 3 serves as a light source of the optical semiconductor device A1, and is capable of emitting visible light. The LED chip 3 is a p-n type semiconductor element with a p-electrode and an n-electrode. The n-electrode is provided on the bottom surface of the LED chip 3, and electrically connected to the die-bonding pad 2Aa of the first electrode 2A via a silver paste 31. The p-electrode is provided on the top surface of the LED chip 3, and electrically connected to the wire-bonding pad 2Ba of the second electrode 2B via the bonding wire 4.

The bonding wire 4 electrically connects the LED chip 3 and the second electrode 2B, and is made of Au, for example. The bonding wire 4 is first bonded to the LED chip 3, and then bonded to the wire-bonding pad 2Ba of the second electrode 2B.

The resin package 5 protects the LED chip 3 and the bonding wire 4. The resin package 5 is molded of a translucent or transparent material such as epoxy resin so that it allows the passage of light emitted from the LED chip 3. The resin package 5 may not be entirely translucent, but may have a reflector for reflecting light emitted laterally from the LED chip 3, so that the light travels in the thickness direction of the substrate 1.

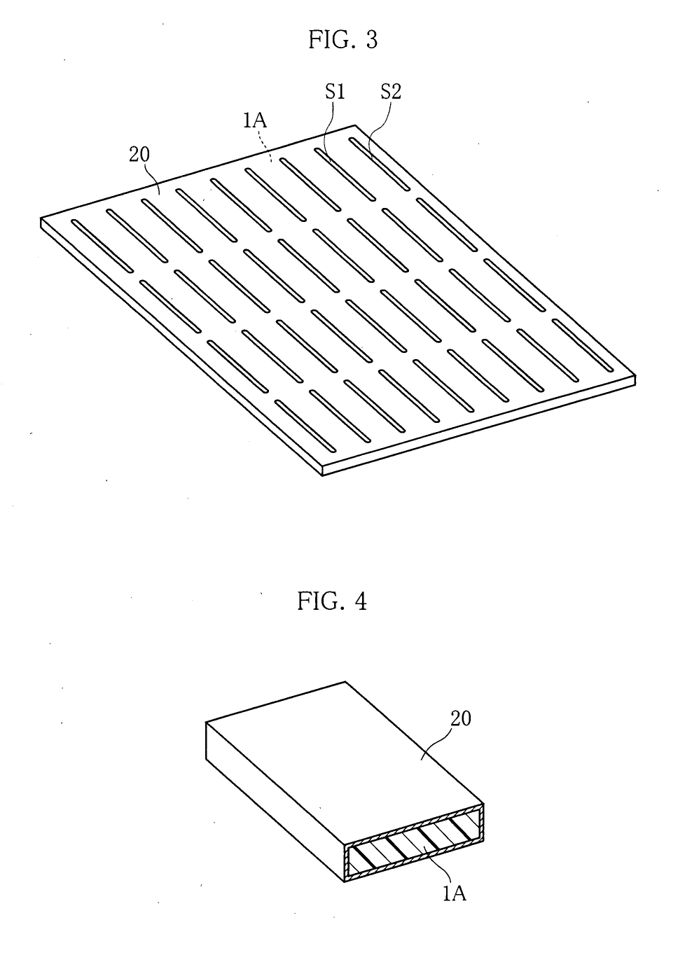

Next, an example of manufacturing method of the optical semiconductor device A1 will be described below with reference to FIG. 3 through FIG. 10.

First, as shown in FIG. 3, a material substrate 1A is prepared. The material substrate 1A is made of e.g. glass epoxy resin, and has an enough dimension to make a plurality of substrates 1 shown in FIGS. 1 and 2. The material substrate 1A is formed with a plurality of elongated slits. A strip portion sandwiched by adjacent slits (slits S1, S2, for example) of the substrate 1A corresponds in size to a plurality of substrates 1 arranged side by side (see FIG. 6). The surface of the material substrate 1A is entirely formed with a base layer 20 by electroless plating using Cu, for example. The base layer 20 has a thickness of about 5 μm-9 μm. FIG. 4 is an enlarged view illustrating the strip portion. As seen from the figure, the base layer 20 is also formed on the inner surfaces of the slits.

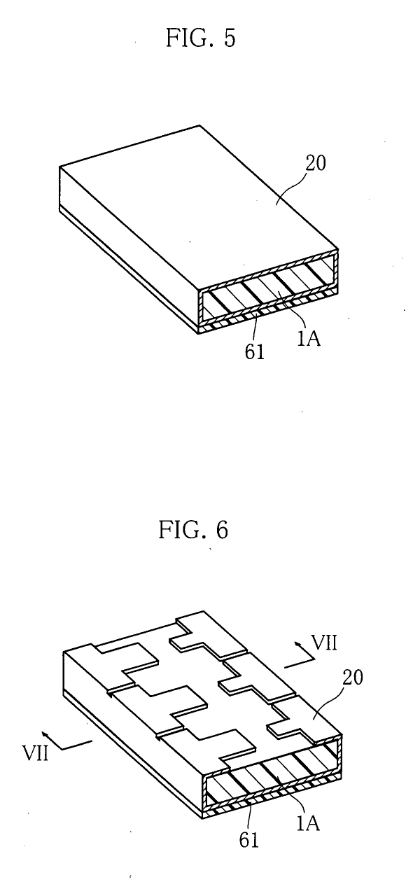

Next, as shown in FIG. 5, a resist film 61 is formed to cover the whole reverse surface of the material substrate 1A. Then, etching using an appropriate mask (not shown) is performed to the base layer 20, at a portion covering the obverse surface of the substrate 1A. In this way, the base layer 20 is shaped as shown in FIG. 6.

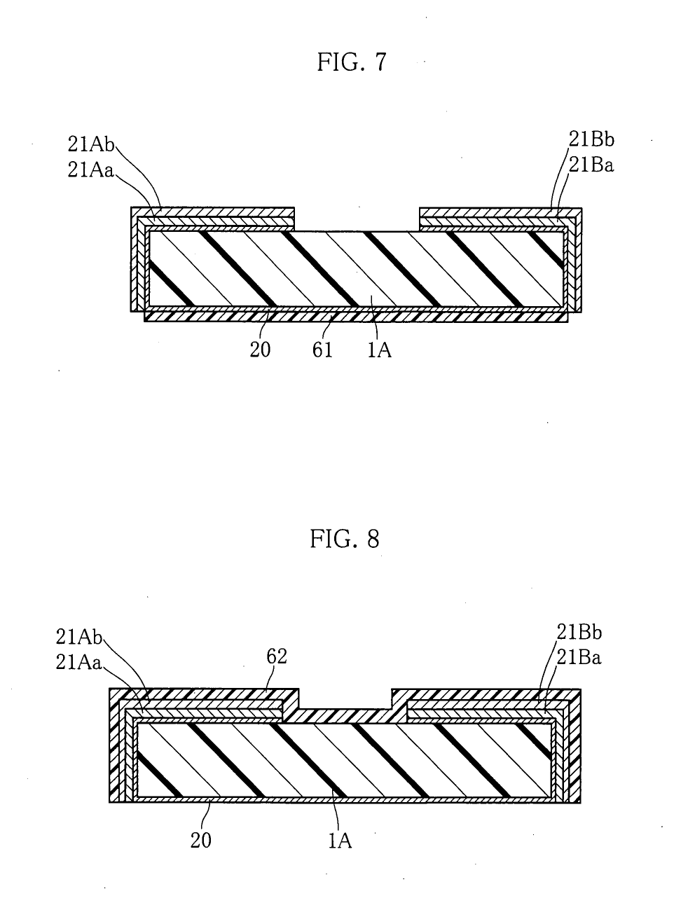

After the etching, as shown in FIG. 7, the first layers 21Aa, 21Ba are formed on the exposed portion of the base layer 20 by electrolytic plating using Ni, for example. The first layers 21A, 21Ba have a thickness of about 5 μm-20 μm. Further, on the first layers 21Aa, 21Ba, the second layers 21Ab, 21Bb are formed by electrolytic plating using Au, for example. The second layers 21Ab, 21Bb have a thickness of about 0.1 μm-0.2 μm. After forming the second layers 21Ab, 21Bb, the resist film 61 is removed.

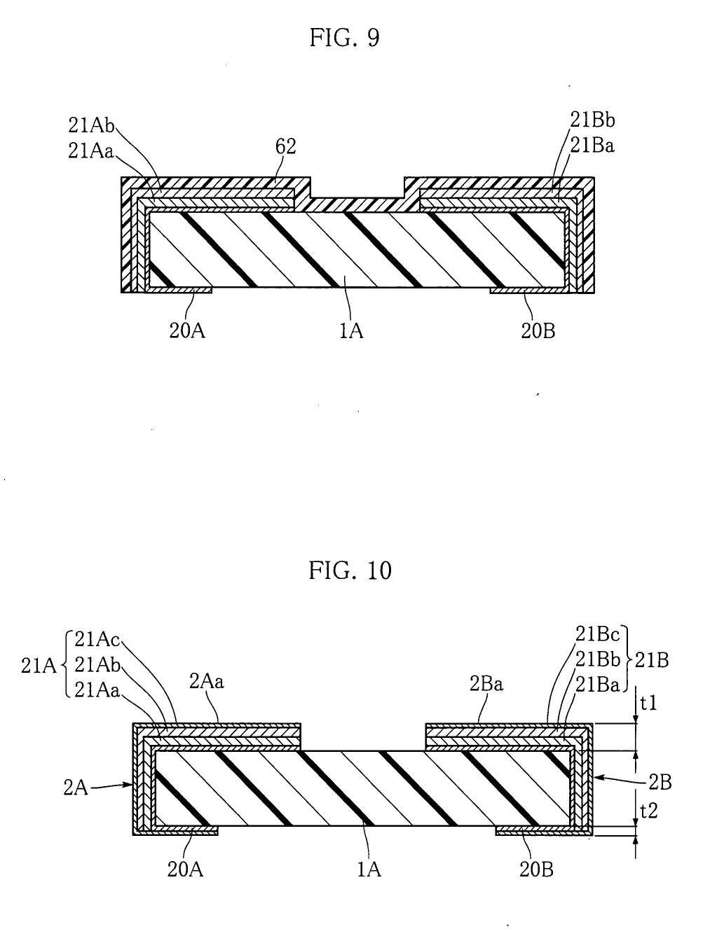

Next, as shown in FIG. 8, a resist film 62 is formed to cover the second layers 21Ab, 21Bb and the exposed portion of the obverse surface of the material substrate 1A (the portion sandwiched by the second layers 21Ab, 21Bb). As a result, the base layer 20 is exposed only at a portion covering the reverse surface of the material substrate 1A. In this state, etching using a mask is performed to remove a portion of the exposed base layer 20 overlapping the middle portion of the reverse surface of the material substrate 1A. In this way, the base layer 20 is divided into the base layers 20A, 20B as shown in FIG. 9. Thereafter, the resist film 62 is removed.

Next, as shown in FIG. 10, the third layers 21Ac, 21Bc are formed by flash plating using Au. The third layers 21Ac, 21Bc cover the second layers 21Ab, 21Bb on the obverse surface and the side surfaces of the material substrate 1A, while also covering the base layers 20A, 20B on the reverse surface of the material substrate 1A. The third layers 21Ac, 21Bc have a thickness of about 0.05 μm-0.3 μm.

According to the above-described process, the first electrode 2A, including the base layer 20A and the plating layer 21A, and the second electrode 2B, including the base layer 20B and the plating layer 21B, are formed. The electrodes 2A, 2B have a thickness t1 of 10 μm-30 μm at portions overlapping the obverse surface and the side surfaces of the material substrate 1A. The electrodes 2A, 2B have a thickness t2 of 5 μm-9 μm at portions overlapping the reverse surface of the material substrate 1A.

Subsequently, the die-bonding of the LED chip 3 to the first electrode 2A, the bonding of the bonding wire 4 to the LED chip 3 and the second electrode 2B, and the molding of the resin package 5 are successively performed. Finally, the material substrate 1A is cut and divided into a plurality of substrates 1, whereby the optical semiconductor device A1 shown in FIGS. 1 and 2 is obtained.

The functions of the optical semiconductor device A1 will be described below.

According to the present embodiment, the bonding wire 4 is bonded to the second electrode 2B at the wire-bonding pad 2Ba having a relatively large thickness. As described above, the thickness t1 of the wire-bonding pad 2Ba of the second electrode 2Ba is 10 μm-30 μm, while the second layer 21Bb has a thickness of 0.1 μm-0.2 μm. With this arrangement, the wire-bonding pad 2Ba is not peeled off by the pressing force during the bonding. Further, the bonding portion of the bonding wire 4 is firmly fixed.

The die-bonding pad 2Aa of the first electrode 2A is as thick as the bonding bad 2Ba (i.e. 10 μm-30 μm). Thus, the LED chip 3 is reliably die-bonded to the pad 2Aa.

On the other hand, the electrodes 2A, 2B have a relatively small thickness t2 of 5 μm-9 μm at the portions overlapping the reverse surface of the substrate 1. When the thickness of plating is relatively small, variations in thickness are reduced. Thus, the problem due to the variations in thickness of the plating can be prevented in making the optical semiconductor device A1. Further, the portions of the electrodes 2A, 2B used for surface mounting are not peeled off even with a relatively small thickness in comparison with the die-bonding bad 2Aa and the wire-bonding pad 2Ba. Since such portions have the relatively small thickness t2 of 5 μm-9 μm, the amount of Au used for making the optical semiconductor device A1 is reduced. Therefore, the production cost of the semiconductor device A1 is reduced.

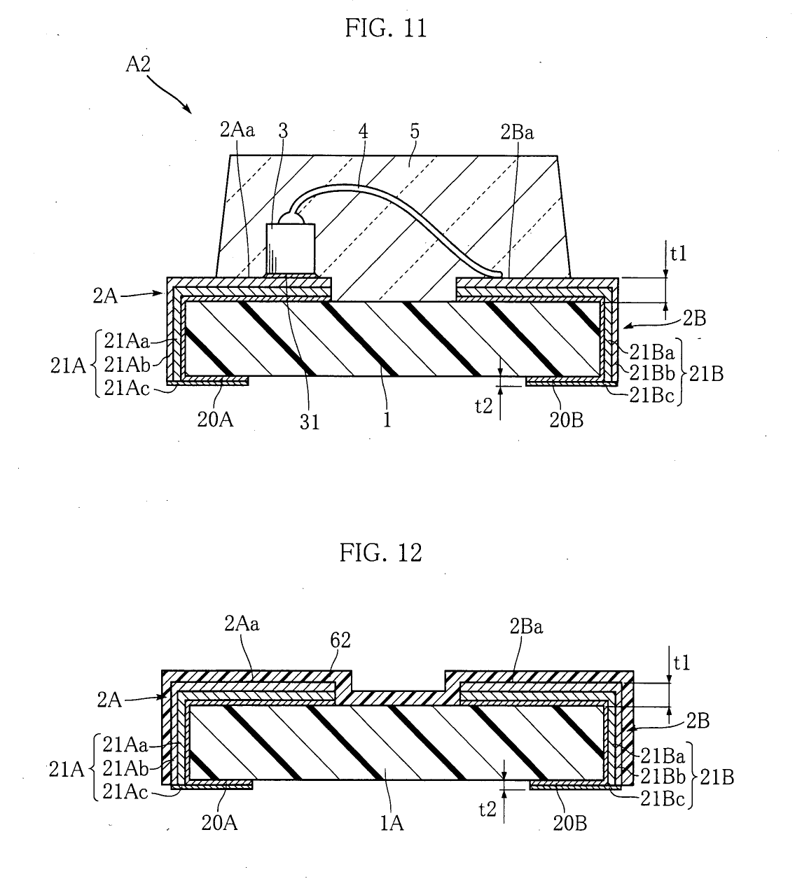

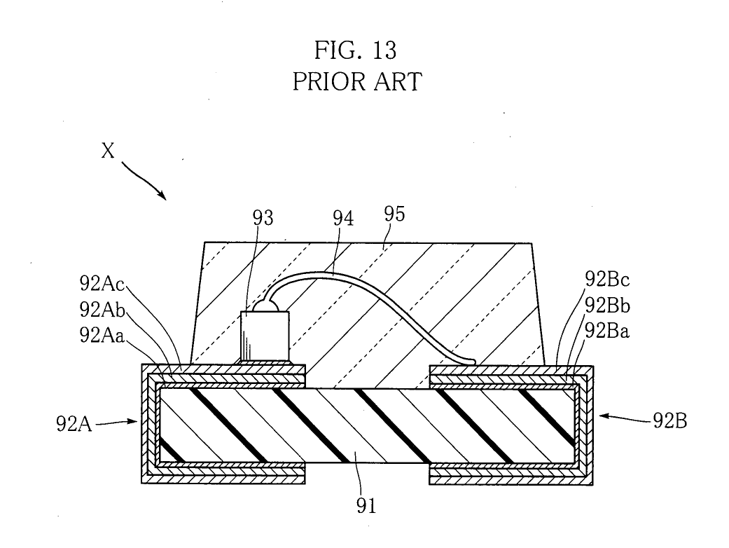

FIG. 11 illustrates an optical semiconductor device according to a second embodiment of the present invention. In the figure, the elements identical or similar to those in the first embodiment are given the same reference numbers.

The illustrated optical semiconductor device A2 differs from the first embodiment in the structure of the plating layers 21A, 21B. Specifically, in the second embodiment, the third layers 21A, 21Bc are formed only on the reverse surface of the substrate 1. At the portions overlapping the obverse surface and the side surfaces of the substrate 1, the plating layers 21A, 21B include only the first layers and second layers 21Aa, 21Ab, 21Ba, 21Bb. The third layers 21Ac, 21Bc are made of Ag, Sn, or solder mainly containing Sn. In the second embodiment, the electrodes 2A, 2B also have a thickness t1 of 10 μm-30 μm at the portions overlapping the obverse surface and the side surfaces of the material substrate 1A. Meanwhile, the electrodes 2A, 2B have a thickness t2 of 5 μm-9 μm at portions overlapping the reverse surface of the material substrate 1A.

The optical semiconductor device A2 can be made by a manufacturing method similar to that of the above-described semiconductor device A1. Specifically, after the same processes as those illustrated in FIGS. 3-9 are performed, the resist film 62 is left unremoved. In this state, as shown in FIG. 12, the third layers 21A, 21Bc are formed only at the reverse surface of the material substrate 1A, overlapping the exposed base layers 20A, 20B. Such third layers 21Ac, 21Bc can be formed of Ag, Sn, or solder mainly containing Sn. Subsequently, as with the optical semiconductor device A1, the die-bonding of the LED chip 3 to the first electrode 2A, the bonding of the bonding wire 4 to the LED chip 3 and the second electrode 2B, and the molding of the resin package 5 are successively performed. Finally, the material substrate 1A is divided into a plurality of substrates 1, whereby the optical semiconductor device A2 shown in FIG. 11 is obtained.

With the above-described structure, the bonding of the bonding wire 4 and the die-bonding of the LED chip 3 are properly performed. Further, the third layers 21Ac, 21Bc of the second embodiment are not formed of Au, but of Ag, Sn, or solder mainly containing Sn. Thus, the production cost of the optical semiconductor device is reduced to a greater extent.

1. An optical semiconductor device comprising:
an insulating substrate including an obverse surface, a reverse surface, and first and second ends spaced from each other;
a first electrode provided at the first end and extending from the obverse surface onto the reverse surface, the first electrode including a die-bonding pad and a first terminal, the die-bonding pad extending on the obverse surface, the first terminal extending on the reverse surface;
a second electrode provided at the second end and extending from the obverse surface onto the reverse surface, the second electrode including a wire-bonding pad and a second terminal, the wire-bonding pad extending on the obverse surface, the second terminal extending on the reverse surface;
an LED chip bonded to the die-bonding pad;
a wire for connecting the LED chip and the wire-bonding pad to each other; and
a resin package enclosing the LED chip and the wire;
wherein the wire-bonding pad has a thickness of 10 μm-30 μm, and the second terminal has a thickness of 5 μm-9 μm.

2. The optical semiconductor device according to claim 1, wherein each of the first and the second electrodes comprises a base layer and a plating layer formed on the base layer.

3. The optical semiconductor device according to claim 1, wherein the die-bonding pad has a thickness of 10 μm-30 μm, and the first terminal has a thickness of 5 μm-9 μm.

4. An optical semiconductor device comprising:
an insulating substrate including an obverse surface, a reverse surface, and first and second ends spaced from each other;
a first electrode provided at the first end and extending from the obverse surface onto the reverse surface, the first electrode including a die-bonding pad and a first terminal, the die-bonding pad extending on the obverse surface, the first terminal extending on the reverse surface;
a second electrode provided at the second end and extending from the obverse surface onto the reverse surface, the second electrode including a wire-bonding pad and a second terminal, the wire-bonding pad extending on the obverse surface, the second terminal extending on the reverse surface;
an LED chip bonded to the die-bonding pad;
a wire for connecting the LED chip and the wire-bonding pad to each other; and
a resin package enclosing the LED chip and the wire;
wherein the die-bonding pad has a thickness of 10 μm-30 μm, and the first terminal has a thickness of 5 μm-9 μm.

5. A method of making an optical semiconductor device, the method comprising the steps of:
forming first and second electrodes on an insulating substrate including an obverse surface and a reverse surface, each of the electrodes extending from the obverse surface onto the reverse surface, each of the electrodes including a base layer and a plating layer formed on the base layer;
bonding an LED chip to a die-bonding pad of the first electrode, the die-bonding pad extending on the obverse surface; and
connecting the LED chip and a wire-bonding pad of the second electrode by a wire, the wire-bonding pad extending on the obverse surface;
wherein the forming of the first and the second electrodes includes a first plating step and a second plating step, the first plating step being performed for forming a plating layer on portions of the base layer other than a terminal portion thereof extending on the reverse surface, the second plating step being performed for forming a plating layer at least on the terminal portion of the base layer.
